(19) United States
(12) Patent Application Publication
(10) Pub. No.: US 2025/0372462 A1
(43) Pub. Date: Dec. 4, 2025

(54) SITU WAFER BOND PROPAGATION MEASUREMENT

(71) Applicant: Tokyo Electron Limited, Tokyo (JP)

(72) Inventors: Andrew Tuchman, Albany, NY (US); Christopher Netzband, Albany, NY (US); Adam Gildea, Albany, NY (US); Ilseok Son, Albany, NY (US)

(21) Appl. No.: 18/678,469

(22) Filed: May 30, 2024

(51) Int. Cl. H01L 21/66; H01L 21/18; H01L 21/67; H01L 21/68; H01L 21/683; H01L 21/822

(52) U.S. Cl. CPC H01L 22/26; H01L 21/187; H01L 21/67092; H01L 21/67288; H01L 21/681; H01L 21/6838; H10D 84/038; H10D 88/01

(57) ABSTRACT

An example method for measuring bond front propagation during bonding includes illuminating, using a first laser beam from a first horizontal optical sensor, a gap between a first wafer and a second wafer, the second wafer held by a second platen over the first wafer. The method includes propagating a bond front to eliminate the gap and forming a bonded region between the first and the second wafers. The method includes while propagating the bond front, collecting, using the first horizontal optical sensor, a first scattered laser beam, the first scattered laser beam including a portion of the first laser beam scattered from the bond front. The method includes determining, using the first scattered laser beam, a first distance from the first horizontal optical sensor to the bond front; and determining, using the first distance, a first position of the bond front during the prop

### TECHNICAL FIELD

The present disclosure relates generally to wafer bonding in semiconductor manufacturing and, more particularly, to in situ wafer bond propagation measurement.

### BACKGROUND

In the semiconductor industry, technological advancement has historically been achieved by scaling down generational technology nodes to ever smaller features and critical dimensions. In recent years, due to a variety of factors including increasing cost and complexity of nodes in nanometer ranges, heterogenous integration of different semiconductor parts into advanced packages has become an increasingly important economic factor in the semiconductor industry. In particular, a need for ever greater numbers of transistors in applications that push performance limits, such as high-performance computing, artificial intelligence (AI)/machine learning (ML), machine vision, and autonomous vehicles and robots, among others, has made such advanced heterogenous packages more economically important. The economic advantages of heterogenous integration can include the ability to combine or mix semiconductor parts from different technology nodes into a single package. In this manner, the complexity or scope of portions of the single heterogenous package that utilize the latest but most resource-intensive technology nodes, e.g., 7 nm or 3 nm nodes, can be reduced or minimized, which can lead to overall economic optimization.

Accordingly, heterogenous integration may represent various methods for bonding parts together, often extending in the vertical direction using processes referred to as hybrid bonding and three-dimensional (3D) integrated circuits (IC). Such hybrid bonded parts may function as a single IC or chip and may exploit different technology nodes for different portions of the final part, in order to optimize costly processing and enable industrial volume scaling. While various types of ICs and bonding methods may be used, hybrid bonded connections are often used to form 3D ICs by directly connecting wafers to other wafers, known as wafer-to-wafer (W2W) bonding, which is an economically favorable approach. In W2W bonding, direct bonding can be used to fuse the two wafers together in a bonding process that also aligns the wafers. Therefore, when W2W bonding for 3D ICs does not proceed properly or completely, alignment issues with individual 3D IC parts can occur, which is not desirable.

In particular, as more semiconductor wafers are bonded together to fabricate 3D ICs using W2W direct bonding, in situ characterization and evaluation of W2W bond integrity during the bonding process has become increasingly important in the semiconductor industry.

### SUMMARY

A method for measuring bond front propagation during bonding includes illuminating, using a first laser beam from a first horizontal optical sensor, a gap between a first wafer and a second wafer, the second wafer held by a second platen over the first wafer. The method includes propagating a bond front to eliminate the gap and forming a bonded region between the first and the second wafers. The method includes while propagating the bond front, collecting, using the first horizontal optical sensor, a first scattered laser beam, the first scattered laser beam including a portion of the first laser beam scattered from the bond front. The method includes determining, using the first scattered laser beam, a first distance from the first horizontal optical sensor to the bond front; and determining, using the first distance, a first position of the bond front during the propagating.

An apparatus for measuring bond front propagation during direct bonding includes a first platen for supporting a first wafer; a second platen for holding a second wafer; and one or more first optical sensors disposed around the first and the second platens, where each of the one or more first optical sensors is configured to measure propagation data including a horizontal distance to a bond front propagating between the first and the second wafers held between the first and the second platens.

A method for controlling a direct bonding process includes aligning a second wafer disposed in a second platen over a first wafer supported by a first platen; striking the second wafer to initiate propagation of a bond front between the first wafer and the second wafer; and during the propagation of the bond front, performing a control loop cycle, one cycle of the control loop cycle including: measuring a rate of bond front propagation; and based on the measured rate of bond front propagation, generating a control signal to change a release rate of the second wafer from the second platen.

### BRIEF DESCRIPTION OF THE DRAWINGS

For a more complete understanding of the present disclosure and its features and advantages, reference is now made to the following description, taken in conjunction with the accompanying drawings, in which:

FIG. 1 is a depiction of a wafer bonding apparatus, in some implementations;

FIG. 2 is a depiction of vacuum zones in a wafer platen, in some implementations;

FIGS. 3A, 3B, 3C, and 3D are depictions of a distance measurement during a wafer bonding process, in some implementations;

FIG. 4 is a depiction of a wafer bonding apparatus, in some implementations;

FIGS. 5A and 5B are depictions of vacuum zones and optical sensors in a wafer platen, in some implementations;

FIG. 6 is a depiction of multiple radial measurements of a W2W bond, in some implementations;

FIG. 7 is a depiction of propagation of a bond front of a W2W bond, in some implementations;

FIG. 8 is a plot of in situ bonding radii during a W2W bonding process, in some implementations;

FIG. 9 is a depiction of a machine learning (ML) model for W2W bond distance calibration, in some implementations;

FIG. 10 is a depiction of a laser sensor, in some implementations;

FIG. 11 is a depiction of a computer system, in some implementations;

FIGS. 12A and 12B are a flowchart depicting a method for wafer bonding, in some implementations;

FIG. 13 is a depiction of a wafer bonding control system, in some implementations;

FIG. 14 is a flowchart depicting a method for measuring bond front propagation during direct bonding; and

FIG. 15 is a flowchart depicting a depicting a method for controlling a direct bonding process, in some implementations.

### DETAILED DESCRIPTION OF ILLUSTRATIVE EMBODIMENTS

In the following description, details are set forth by way of example to facilitate discussion of the disclosed subject matter. It should be apparent to a person of ordinary skill in the field, however, that the disclosed embodiments are exemplary and not exhaustive of all possible embodiments.

Throughout this disclosure, a hyphenated form of a reference numeral refers to a specific instance of an element and the un-hyphenated form of the reference numeral refers to the element generically or collectively. Thus, as an example (not shown in the drawings), device “12-1” refers to an instance of a device class, which may be referred to collectively as devices “12” and any one of which may be referred to generically as a device “12”. In the figures and the description, like numerals are intended to represent like elements.

As noted above, the semiconductor industry has embraced 3D packaging to enable hybrid devices, such as that stack bonded die together and mix different technology nodes in a single final product for economic benefits. In practice, such 3D ICs are often fabricated using W2W bonding that produces multiple 3D ICs or chips in a single operation for economical reasons, which can then be sliced apart from the bonded wafers. The W2W bonding process, therefore, also includes alignment of the wafers to each other such that the W2W bonding results in each 3D IC formed on the wafers being bonded together in an aligned manner within specified tolerances.

Ideally, each semiconductor wafer is assumed to be substantially planar, such as being near perfectly flat. However, it is observed that in certain implementations, such as where multiple layers of different types of semiconductor materials (e.g., conductors, dielectrics, semiconductors) are formed as IC devices on a wafer, the wafer may exhibit a certain degree of bowing or warping, or more generally, some non-planarity that can result in localized vertical dimensional variations. For example, localized vertical variations resulting from wafer bowing up to 1,000 μm in some instances may be observed.

Specifically, in the case of forming 3D ICs using W2W bonding, some or all layers of the IC devices formed on each wafer can be completed before W2W bonding is performed. For example, certain back-end of line (BEOL) layers that can include conductors, barrier layers, and dielectric insulators may comprise numerous numbers of layers, which, in combination with the multiple layers of front-end-of-line (FEOL) portions of the IC, can result in different types of adjacent materials being subject to different thermal loads and cycling during various fabrication steps and process conditions. Thus, some individual wafers can exhibit certain residual stresses that result from the fabrication of multiple such ICs having respective multi-layered structures, such as tensile or compressive stresses in a lateral direction along the wafer. In some wafers, these residual stresses can result in outright bowing or warping, e.g., vertical variances in the wafer height at certain locations. Even when bowing or warping is not observed or is not apparent in a wafer, the residual stresses may still be present and may affect the wafer bonding process to facially bond two wafers together. It has also been observed that non-uniform W2W bond propagation, as discussed in further detail below, which can result from wafer warping or bowing, can be related to a pattern density of the 3D ICs formed in the wafer, and can be expected as an ongoing issue with increasing IC pattern densities on wafers.

For the W2W hybrid bonding technique, two wafers can be face bonded together, as noted above. Then, the bonded wafer can be diced into individual die pairs that have been W2W bonded together.

The W2W bonding technique serves to form a face-to-face or surface bond between two semiconductor parts. The bonding surfaces may be prepared to facilitate a bond having sufficient bond strength, such as by plasma treatment of each surface to be bonded, or other chemical preparation steps for direct bonding. In various embodiments, CMP and other surface treatments may be used to prepare the part surfaces to be bonded together, among other processing steps. The part surfaces on a wafer to be bonded with another wafer can comprise metals, semiconductors, dielectrics, polymers, or other materials, in various implementations.

As noted, in direct bonding, the bonded surfaces may comprise a silicon-to-silicon, silicon-to-dielectric or dielectric-to-dielectric bond. Dielectric materials may include nitrides, oxides, carbonitrides or the like, e.g. silicon oxide, silicon nitride, silicon carbide, silicon carbonitride or the like. The bonded surfaces of W2W bonds may additionally comprise metallic conductor bonds, such as copper-copper bonds, as is typical in conventional hybrid bonding processes for forming electrical interconnections in 3D IC parts. In some cases, the bonding technique may employ an adhesive that is applied to facilitate the face-to-face bond. In particular implementations, direct W2W bonding is done without an adhesive by preparing the bonding surfaces to spontaneously bond when the bonding surfaces are placed in contact with each other, and after the bond is initiated, such as with an input of mechanical force, such as with a pin or a striker at a center portion of the wafers. The spontaneous bond can then propagate outwards from the center portion to the edge or periphery of the wafers.

Accordingly, various techniques and applications may rely on W2W bonding to create wafer bonds having a desired bond strength. One aspect of the present disclosure is to accurately ascertain bond quality information during the bonding process.

As 3D ICs become more complex, and as feature sizes become smaller and smaller in dimension, the tolerances for such variances in bonding performance may also become stricter. As noted above, bowing or warping of certain portions of wafers that are subject to W2W bonding may not be predictable. Whether due to actual bowing/warping or due to other variances in local mechanical properties, such irregularity in wafer properties can, if not accounted for, result in undesirable deviations during the W2W direct bonding process, such as voids or incomplete bonding at certain locations.

The typical direct W2W bonding process involves aligning one wafer with a second wafer in two aligned platens (also referred to as wafer chucks, or chucks) in a bonding apparatus that is enabled for placing the two wafers in proximity to each other and initiating the direct bond. The wafers may be aligned using alignment patterns and aligned such that the crystallographic directions of the wafers are aligned. In some W2W direct bonding processes, the mechanical bonding can be followed by subsequent annealing or other treatment to solidify the bond, or otherwise make the bond permanent, in particular implementations. For example, a first wafer (e.g., the lower wafer) in the bonding apparatus can be held fixed while being forced into a planar shape, while a second wafer (e.g., the upper wafer) in the bonding apparatus can be retained in alignment with the first wafer, yet still be bonded to the first wafer that is held in the planar shape. As a result, the bonding process may propagate through the second wafer as a deformation wave that goes outwards from the wafer center to the wafer edge as the two wafers are facially bonded. In various implementations, such W2W direct bonding can occur within a short time, such as measured in a few seconds, as described in further detail below.

As noted above, in bonding cases having nominal variance, the W2W direct bond can propagate more or less uniformly from the wafer center to the wafer edge in a circumferential manner (e.g., with low eccentricity), and does not result in any misalignment of the wafers, with a uniform bond integrity across the gap, which is desirable. However, in bonding cases having greater than nominal variance, such as where residual stresses or other factors cause non-planarity, among other issues, the predetermined direct bonding parameters used may not be sufficient or effective to result in a W2W bond having desired quality. A sufficient quality W2W bond can be characterized as being absent substantial voids or gaps, and having desired alignment at facial portions of the wafers, such that the 3D IC devices on the wafers are properly aligned (e.g., within an alignment tolerance), among other quality features of the bond. Thus, when the W2W direct bond does not progress with nominal variance based on the normal bonding process parameters, the quality of the W2W bond can be adversely affected, which can, in turn, adversely impact the quality of the 3D ICs being fabricated, or even a per wafer part yield. In other words, non-uniform bond propagation of the W2W direct bond can increase misalignment of 3D ICs being fabricated, which is undesirable.

Typical W2W bond quality measurement techniques have used infrared (IR) radiation to illuminate through the wafer pair (e.g., transmission normal to the wafer face) to ascertain a 2D representation of the bond quality over the gap between the wafers. However, the instrumentation for such transmissive IR imaging over the gap between the wafers is not typically compatible with actual wafer bonding equipment used with the wafer pair during W2W bonding, and such instrumentation is typically complex so as to interfere with bonding platen operation. As a result, typical in situ W2W bond quality measurements have been limited, such as to a few discrete points at the gap that may not provide adequate measurement of bond propagation. Thus, typical IR-based W2W bond quality measurements cannot verify a complete and acceptable bond when the wafers are mounted in the bonding apparatus, and cannot provide an in situ indication of remedial action that could correct any problems with the bond during the bonding process, which is undesirable.

As will be described in further detail herein, certain implementations describe methods and systems for in situ wafer bond propagation measurement. Certain implementations are compatible with existing W2W bonding apparatus. Certain implementations provide in situ bond propagation measurement that can be used for in situ remedial action during direct bonding. Certain implementations can validate when bond propagation is acceptable, such as within specified tolerances. Certain implementations can thoroughly cover the W2W bond propagation over the gap between the two wafers. Certain implementations can be used to prevent wafer or IC part misalignment during W2W bonding, and thereby, improve wafer and/or part yields.

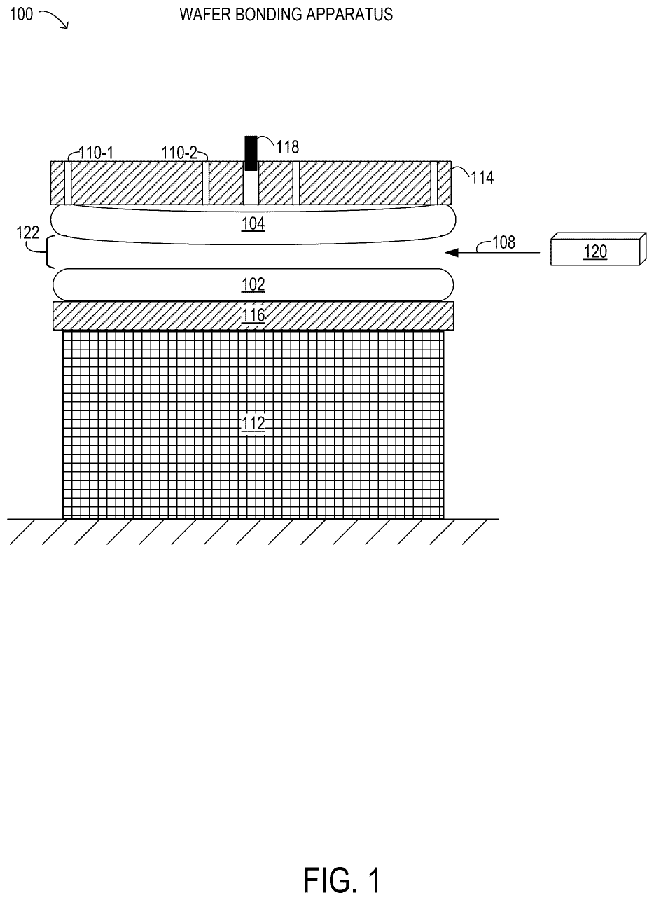

Referring now to the drawings, FIG. 1 is a depiction of a wafer bonding apparatus 100 (or simply apparatus 100), in some implementations. FIG. 1 is a schematic drawing and is not drawn to scale or perspective. FIG. 1 is a generalized schematic for descriptive purposes and is not limiting for any particular design or structure or functionality associated with in situ wafer bond propagation measurement, as disclosed herein. As shown in FIG. 1, wafer bonding apparatus 100 may be used in a chamber for controlling an environment during use, such as a vacuum chamber or a gas pressurized chamber, in some implementations. Furthermore, the arrangement and orientation of apparatus 100 is shown in FIG. 1 as an example for descriptive purposes and can vary in different implementations.

As shown in FIG. 1, wafer bonding apparatus 100 includes a base portion 112 that supports a lower platen 116 (also referred to as a fixture or a chuck) that can receive a first wafer 102 for W2W bonding. Lower platen 116 can include or represent a wafer chuck or a wafer fixture that mechanically retains first wafer 102 in a precisely aligned location, while allowing first wafer 102 to be mounted and removed. Furthermore, lower platen 116 can retain first wafer 102 in a planar or substantially flat state, such that an upper surface of first wafer 102 is planar within a desired tolerance for W2W bonding (e.g., no bowing nor warping of first wafer 102). Accordingly, lower platen 116 can include means to grip or retain first wafer 102, such as a vacuum chuck that can provide sufficient vacuum force to retain first wafer 102 in the planar condition, even when first wafer 102 naturally bows or warps to a certain degree. In some embodiments, lower platen 116 can retain first wafer 102 without making contact, for example, using an electrostatic chuck. In another example, lower platen 116 can provide a planar surface to which first wafer 102 is tightly held. Lower platen 116 can also include thermal regulation for maintaining first wafer 102 at a desired temperature.

In a similar manner as lower platen 116 with first wafer 102, upper platen 114 can include or represent a wafer chuck or a wafer fixture that mechanically retains second wafer 104 in a precisely aligned location, while allowing second wafer 104 to be mounted and removed. However, for the purposes of W2W bonding, upper platen 114 can retain second wafer 104 with a slight degree of concavity facing upward, or convexity facing downward, as shown in FIG. 1, which may represent a normal bowing of second wafer 104. Accordingly, upper platen 114 can include means to grip or retain second wafer 104, such as vacuum nozzles 110 that can provide sufficient vacuum force to retain second wafer 104 in the concave upward condition, as shown in FIG. 1.

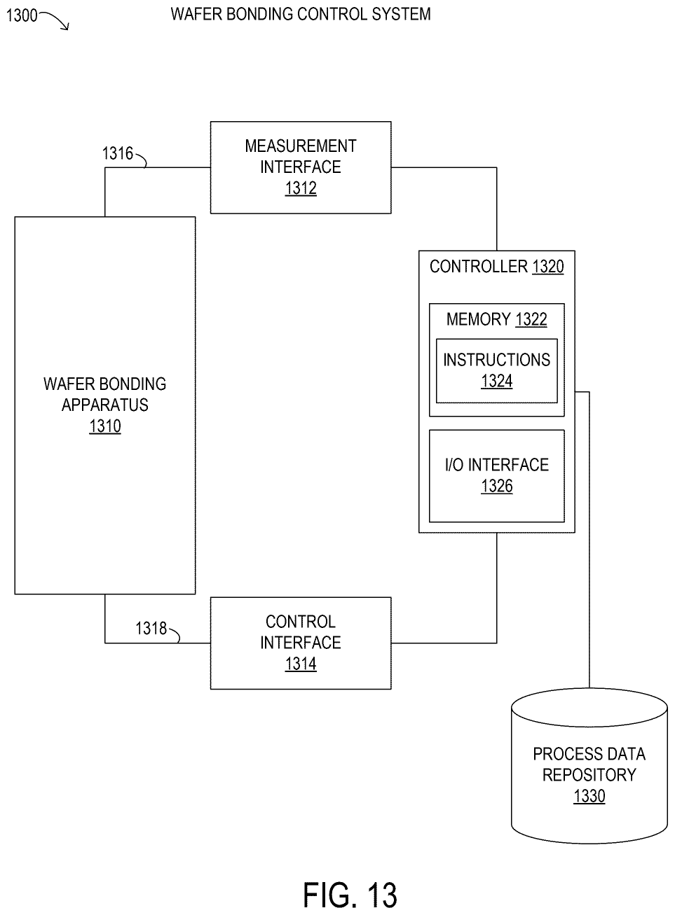

Specifically, a first vacuum nozzle 110-1 is shown at a peripheral portion of upper platen 114, while a second vacuum nozzle 110-2 is shown at a central portion of upper platen 114, corresponding to peripheral and central portions of second wafer 104. First and second vacuum nozzles 110 can be individually controlled, such as for applying a desired vacuum pressure at a certain time, for various operations related to wafer bonding. For example, vacuum nozzles can be controlled by a wafer bonding control system 1300 (see FIG. 13). As shown, when second wafer 104 is shaped slightly convex upward, first vacuum nozzle 110-1 may retain second wafer 104 closely at the peripheral portions, while second vacuum nozzle 110-2 may allow second wafer 104 to bow downwards at a center portion. Also at the center portion is a bonding mechanism 118 that may be a pin or a striker than initiates a direct bond between first wafer 102 and second wafer 104 at the central portion. Once the direct bond is initiated at the central portion, the bond may propagate outwards towards the peripheral portion.

Accordingly, vacuum nozzles 110 can be controlled to perform a release sequence in which vacuum pressure is released at certain points during the bond propagation. In particular implementations, the release sequence can be predetermined, such as by using predefined time intervals. In some implementations, as disclosed herein, the release sequence can be modified based on bond propagation data that is collected and analyzed during bonding to indicate a corrective action, such as when the bond propagates in an eccentric manner with respect to the center portions. In various implementations, the corrective action can be associated with the second platen, and be selected from at least one of: modifying a vacuum pressure associated with the at least one vacuum nozzle 110, modifying a release time associated with the at least one vacuum nozzle 110, modifying a selection of the at least one vacuum nozzle 110 for applying the vacuum pressure, or modifying a release sequence of the at least one vacuum nozzle 110.

Also shown in FIG. 1 is a gap 122 that defines a region between the two opposing faces of first wafer 102 and second wafer 104. Gap 122 can represent the region between the two opposing wafer faces for various distances of separation, such as spaced apart as shown in FIG. 1, up to and including a bonded condition when a W2W direct bond (also referred to as a direct bond or a joint) is formed across gap 122 between first wafer 102 and second wafer 104 that are then in contact with each other.

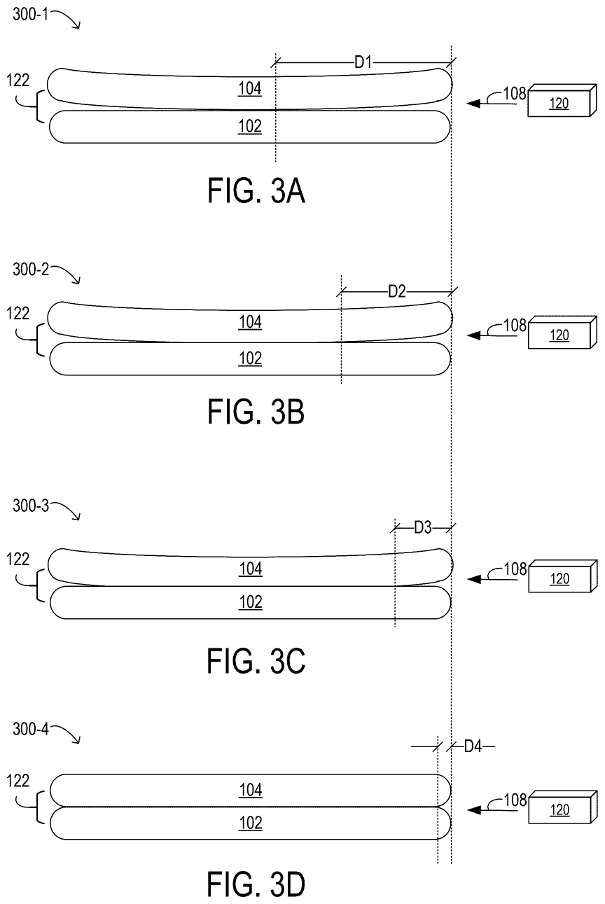

In operation of wafer bonding apparatus 100, first wafer 102 and second wafer 104 can be prepared for W2W direct bonding, such as by undergoing suitable pre-treatment steps of planarization (e.g., by CMP), polishing, cleaning, and chemical surface treatment, plasma treatment, among others. When first wafer 102 and second wafer 104 are in condition for W2W direct bonding, the wafers can be mounted into apparatus 100 as shown and described above. Then, after the wafers are positioned in sufficient proximity to each other to initiate the direct bond, the direct bond can be initiated using bonding mechanism 118. As a result, a central portion of second wafer 104 initially contacts a correspondingly aligned central portion of first wafer 102, which initiates the W2W direct bond at the central portion. Then, a bond front (also referred to as a joint front) of the W2W direct bond propagates outward radially over gap 122. As noted, the bond front can thus propagate radially over gap 122 until the W2W direct bond reaches the edge portions of gap 122, corresponding to the edges of first wafer 102 and second wafer 104, which can occur within a few seconds, such as in less than 10 seconds, or in less than 15-20 seconds, in various implementations (see also FIGS. 3A-3D).

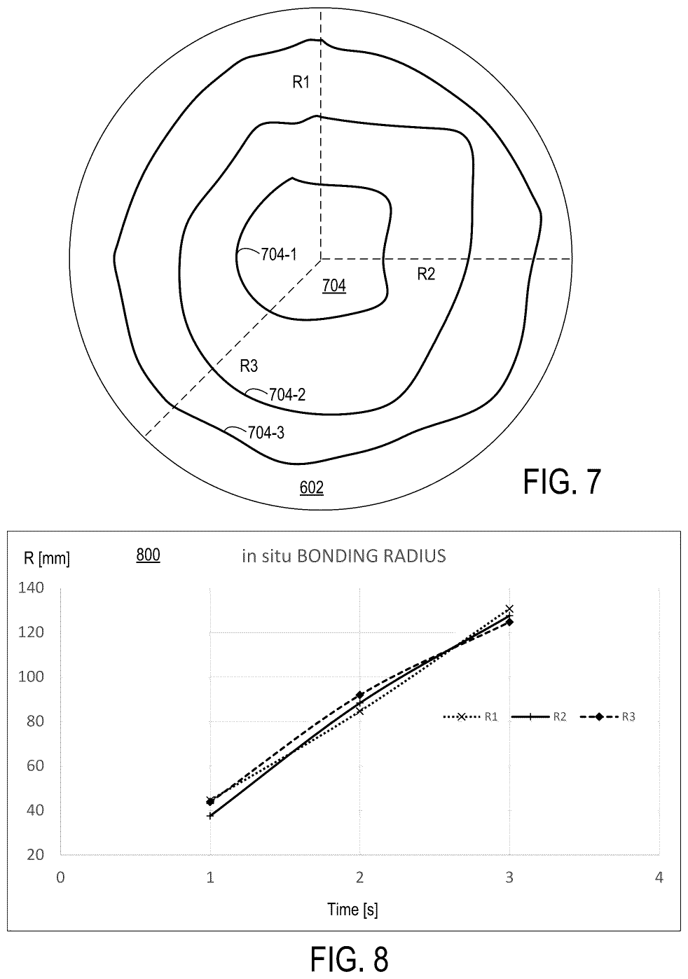

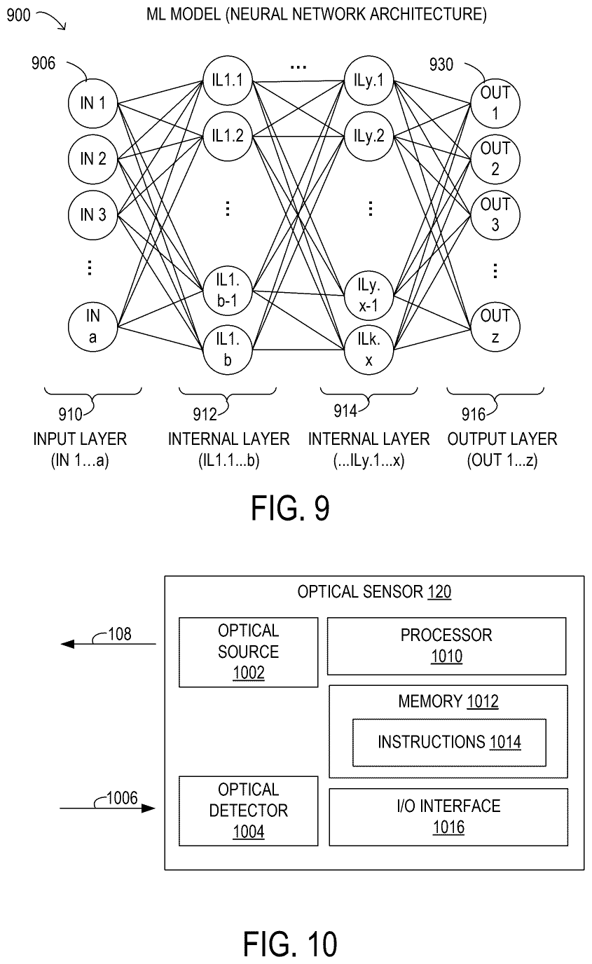

Furthermore, wafer bonding apparatus 100 is shown in FIG. 1 including a horizontal optical sensor 120 that can measure a distance to an object located away from horizontal optical sensor 120 (see also FIG. 9). Specifically, horizontal optical sensor 120 can generate a laser beam 108 that can be used for distance measurement to an edge of the W2W direct bond, such as by directing laser beam 108 to gap 122 in situ as second wafer 104 is bonded to first wafer 102 using apparatus 100. By measuring a distance from horizontal optical sensor 120 to the W2W bond, and given a fixed location of horizontal optical sensor 120 relative to first wafer 102 and second wafer 104, a bond radius of the W2W bond can be measured in situ as the W2W bond front propagates outward over gap 122 (see also FIGS. 7 and 8). By measuring the bond radius in situ during the W2W direct bonding process, horizontal optical sensor 120 can be used to detect when the bond front is not propagating in a nominal manner, such as outside of an acceptable tolerance value. When horizontal optical sensor 120 detects such an anomalous deviation that could adversely impact the quality of the W2W bond, an indication can be generated to modify the direct bonding process in progress, along with information from horizontal optical sensor 120 relating to the nature of the anomalous deviation, such as location, size, extent, among other factors. In this manner, potential W2W direct bonding errors can be detected in situ and can be averted or remediated to preserve the quality of the W2W bonded wafer and the 3D IC parts included therewith.

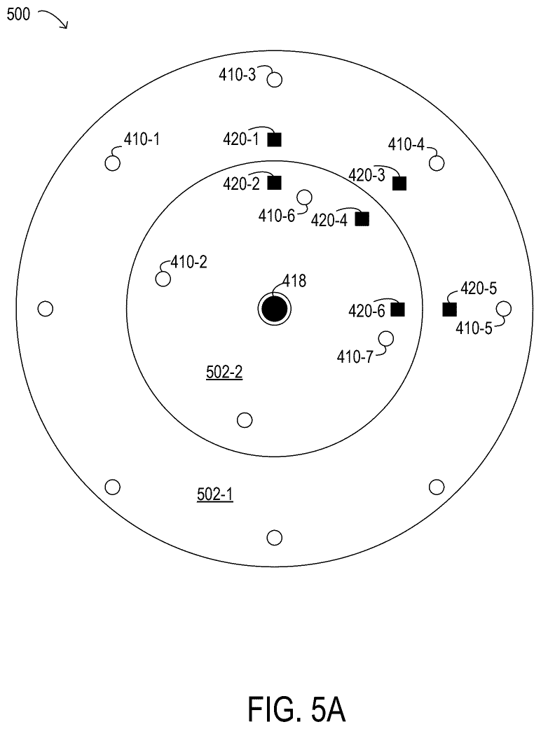

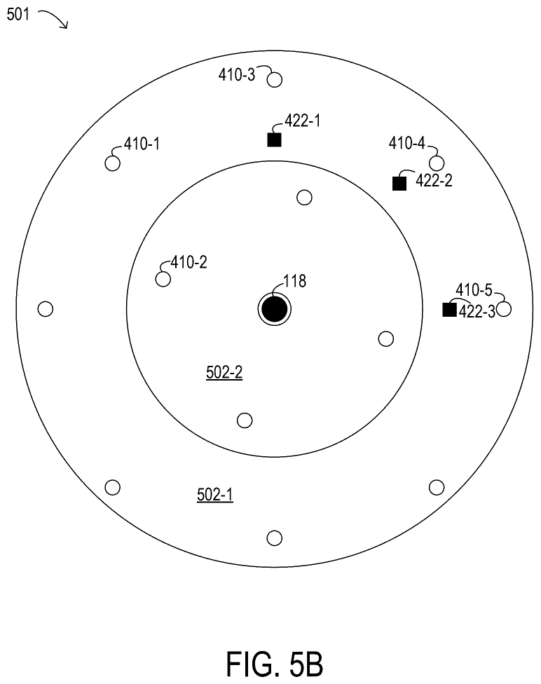

In particular implementations, laser beam 108 can be directed to a center of gap 122 corresponding to the center of first wafer 102 and second wafer 104 that are precisely aligned in apparatus 100, as noted above. Thus, laser beam 108 can be a radial beam that measures along one particular bond radius, depending on a location of horizontal optical sensor 120 that is typically fixed. However, multiple horizontal optical sensors 120 and corresponding multiple laser beams 108 can be used to improve measurement coverage of the W2W bond during propagation, such as by mounting the horizontal optical sensors 120 at multiple radial locations, each pointing to the center (see also FIG. 5). In this manner, as additional horizontal optical sensors 120 can be added and used along different radial locations, an improved (or more complete) in situ depiction of a joined area of the W2W bond, including the radial shape of a bond front of the W2W bond, can be obtained, which is desirable for more accurately monitoring and controlling bond quality. Various methods can be used to disambiguate multiple bond radius measurements performed in this manner, such as by time multiplexing, frequency modulation, code modulation, phase modulation, amplitude modulation, among other signal disambiguation techniques. It is noted that horizontal optical sensor 120 can typically support a relatively high rate of bond radius measurements, such as 100 samples/s, 500 samples/s, 1,000 samples/s, or even 10,000 samples/s in various implementations, in order to provide precise tracking of the bond front and be able to respond without excessive delay when a bond anomaly is detected.

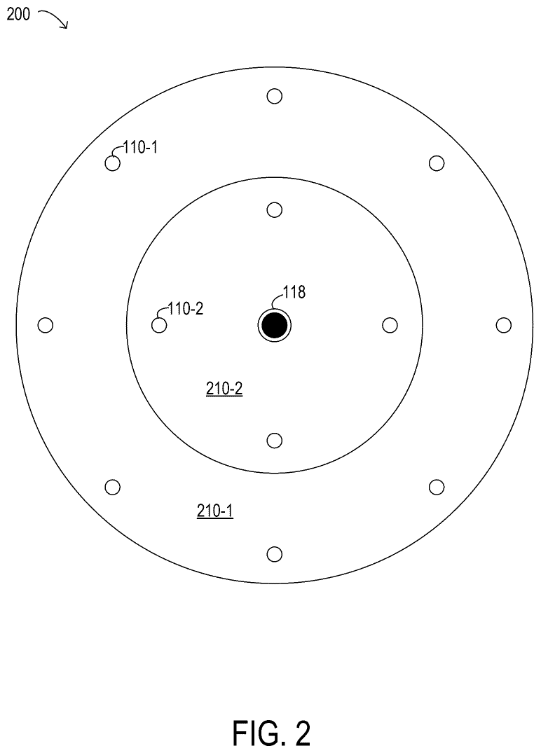

FIG. 2 is a depiction of vacuum zones 210 in a wafer platen 200, in some implementations. FIG. 2 is an exemplary schematic depiction. Wafer platen 200 can be a depiction of a surface of upper platen 114 that retains second wafer 104 and correspondingly mates with a surface of second wafer 104. Specifically, in wafer platen 200, a first vacuum zone 210-1 at a peripheral portion and a second vacuum zone 210-2 are shown at a central portion that includes bonding mechanism 118. Also in FIG. 2, first vacuum nozzles 110-1 are included in first vacuum zone 210-1 and second vacuum nozzles 110-2 are included in second vacuum zone 210-2. Various other arrangements and numbers of vacuum zones 210 can be used in different implementations. For example, a number or a size of vacuum nozzles 110 can vary in different embodiments. In some embodiments, different diameters of vacuum nozzles 110 can be used together.

As noted, the operation of vacuum zones 210 and vacuum nozzles 110 can be used for controlling the retention of second wafer 104 during the direct bonding process, as the bond front propagates outwards. For example, a release sequence involving vacuum zones 210 or individual vacuum nozzles 110 may be used to release second wafer 104 as the direct bond front propagates outwards. When measured bond front propagation data collected during the bonding process indicate a deviance from a desired tolerance, such as an excessive degree of eccentricity of propagation of the bond front, corrective action with respect to vacuum nozzles 110 can be taken to reduce the eccentricity. For example, vacuum nozzles 110 can be controlled with a desired vacuum pressure, such as to release second wafer 104 in situ during bond front propagation at such times and radial locations where the bond front has propagated too slowly, such as to accelerate the bond front. In other cases, the desired vacuum pressure may be maintained longer at such times and radial locations where the bond front has propagated too quickly, such as to retard the bond front.

FIGS. 3A, 3B, 3C, and 3D are depictions of a distance measurement during a wafer bonding process 300, in some implementations. Wafer bonding process 300 is depicted for first wafer 102 and second wafer 104 as used with wafer bonding apparatus 100 described above with respect to FIG. 1. Accordingly, in Wafer bonding process 300, it is assumed that first wafer 102 and second wafer 104 are aligned to each other for the direct bonding process, as described above with respect to FIG. 1. Also depicted in Wafer bonding process 300 is gap 122, along with horizontal optical sensor 120 that illuminates gap 122 using laser beam 108 in order to make distance measurements from horizontal optical sensor 120 to a bond front of the W2W bond in situ.

Specifically, laser beam 108 is directed in a direction parallel to gap 122 and is vertically aligned with gap 122, allowing laser beam 108 to illuminate the W2W bond in situ, and to receive backscattered light from the bond front of the W2W bond as the bond front propagates outward from the center of gap 122. The backscattered light can be received by an optical detector included with horizontal optical sensor 120 that can be used to generate the distance measurements (see also FIG. 10). It is noted that, in Wafer bonding process 300, second wafer 104 is shown ideally conforming in a progressive manner with a planar surface of first wafer 102, thus depicting a W2W bond having nominal variance that is within acceptable tolerances, such as for planarity and completeness of adhesion.

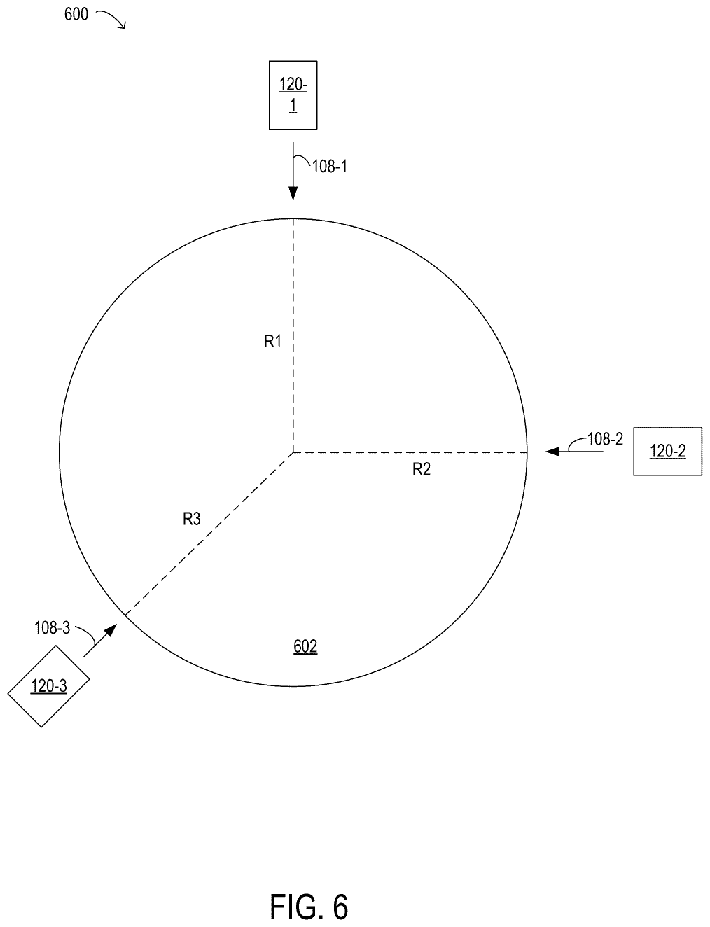

In FIG. 3A, wafer bonding process 300-1 is shown being initiated at a center portion of gap 122 resulting in a measurement of distance D1. In FIG. 3B, Wafer bonding process 300-2 is shown having a bond front propagated outwards from the center portion of gap 122 resulting in a measurement of distance D2 that is shorter than distance D1. In FIG. 3C, Wafer bonding process 300-3 is shown having the bond front propagated outwards from the center portion of gap 122 even further, resulting in a measurement of distance D3 that is shorter than distance D2. Finally, in FIG. 3D, Wafer bonding process 300-4 is shown having the bond front propagated completely to the edge of the first wafer 102, resulting in a measurement of distance D4 that is shorter than distance D3, and represents a shortest distance measured that corresponds to a complete bond between the first wafer 102 and the second wafer 104. It is noted that while one horizontal optical sensor 120 is shown in Wafer bonding process 300, multiple horizontal optical sensors 120 can be used to generate multiple distance measurements, such as substantially simultaneously in an in-situ manner, while the bond front propagates outward to the edge of gap 122 (see also FIGS. 6, 7 and 8).

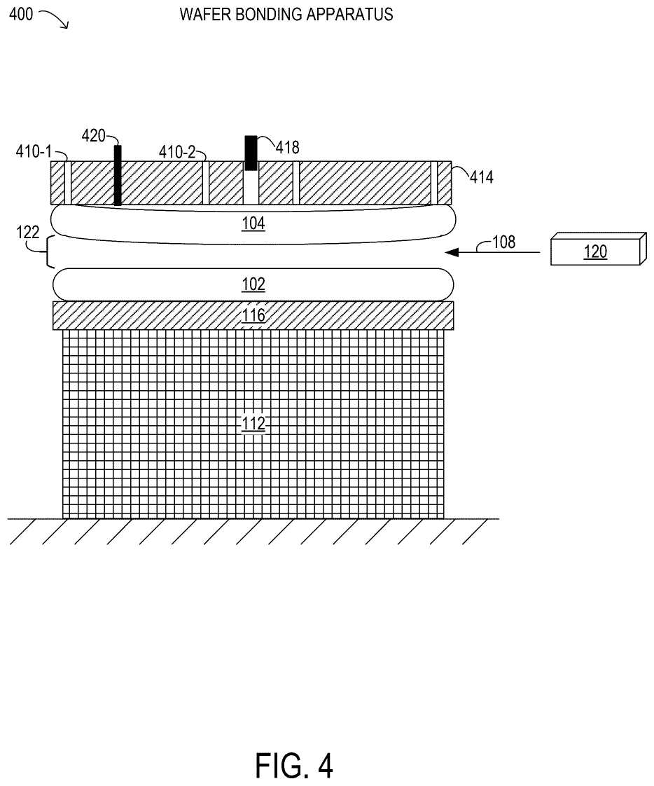

FIG. 4 is a depiction of a wafer bonding apparatus 400, in some implementations. Wafer bonding apparatus 400 is similar to wafer bonding apparatus 100 shown and described with respect to FIG. 1. However, in wafer bonding apparatus, an upper platen 414 includes vacuum nozzles 410-1 and 410-2 similar to vacuum nozzles 110, a bonding mechanism 418 similar to bonding mechanism 118, and also one or more optical sensors 420. Optical sensor 420 can be used to vertically measure a distance to a surface of second wafer 104, such as when second wafer 104 is mounted or retained in upper platen 414. Optical sensor 420 can be any of a variety of optical distance sensors, such as using a laser beam as a light source. The optical sensors 420 may be a time-of-flight (ToF) sensor, optical spectrometer to measure reflected intensity, and others. In this manner, optical sensor 420 can be used to detect the bond front when the bond front passes a location where optical sensor 420 is installed in upper platen 414 (see also FIGS. 5A and 5B).

FIGS. 5A and 5B are depictions of vacuum zones 502 and vertical optical sensors 420 and 422 in a wafer platen 500 and 501, respectively, in some implementations. Wafer platen 500 and 501 are similar to wafer platen 200 in FIG. 2. Wafer platen 500, 501 show vacuum zones 502-1 and 502-2 similar to vacuum zones 210 in FIG. 2. Wafer platen 500, 501 show vacuum nozzles 410-1 and 410-2 similar to vacuum nozzles 110 in FIG. 2.

In FIG. 5A, wafer platen 500 includes six (6) vertical optical sensors 420-1, 420-2, 420-3, 420-4, 420-5, and 420-6 that are located at different radial angles and at different distances from center.

Specifically, vertical optical sensors 420-1 and 420-2 are located along a Y-axis, while vertical optical sensors 420-5 and 420-6 are located along an X-axis, which may represent arbitrary axes. Vertical optical sensors 420-3 and 420-4 are located at 45 degrees to the X-axis and the Y-axis. Vertical optical sensors 420-1, 420-3, and 420-5 are located in vacuum zone 502-1, while vertical optical sensor 420-2, 420-4, and 420-6 are located in vacuum zone 502-2. As a result of their locations, optical sensors 420 can be configured to detect a bond front that propagates from the center of wafer platen 500 and 501, such as from bonding mechanism 418 outwards. In particular, vertical optical sensors 420-2, 420-4, and 420-6 located in vacuum zone 502-2 can be used to respectively capture first timestamps when a vertical deflection of second wafer 104 is detected at their respective locations. Vertical optical sensors 420-1, 420-3, and 420-5 located in vacuum zone 502-1 can be used to respectively capture second timestamps, occurring after first timestamps, when a vertical deflection of second wafer 104 is detected at their respective locations.

The first timestamps can be compared to each other to provide an indication of a first eccentricity of the bond front with respect to the center of wafer platen 500, while second timestamps can be compared to each other top provide an indication of a second eccentricity of the bond front at a later time. Furthermore, first timestamps and second timestamps from vertical optical sensor 420-2 and 420-1, 420-4 and 420-3, 420-6 and 420-5 can be used to interpolate respective velocities of the bond front in situ along the respective radial lines (e.g., axes) where vertical optical sensors 420 are located. In particular embodiments, the respective velocities can be compared with bond radii measured in situ using horizontal optical sensor 120, as described herein, such as to provide additional bond front propagation data, or correlation of bond front propagation data. Such insights can be used for determining any corrective action to be taken for direct bonding, for example, corrective action taken in situ during the direct bonding process.

The corrective action taken can depend on a location of a vertical optical sensor 420. For example, in wafer platen 500, at the first timestamp, a timing of vacuum release of second wafer 104 by vacuum nozzles 410-6 and 410-7 can be controlled, such as by turning off or reducing the vacuum pressure. At the second timestamp, a timing of vacuum release of second wafer by vacuum nozzles 410-3, 410-4, and 410-5 can be correspondingly controlled. The arrangement and number of optical sensors and vacuum nozzles described above is exemplary and non-limiting, and various different arrangements and numbers of optical sensors and vacuum nozzles can be used in different embodiments. The control of the timing of vacuum release in wafer platen 500 in this manner can be used to affect completion of the direct bonding process and can be used, for example, to control subsequent stress and distortion between the wafer pair to be bonded. Furthermore, bond radii measurements performed in situ using horizontal optical sensor 120, as described herein, can also be used to augment measurement data forming the basis of the corrective action taken in situ in a similar manner as with vertical optical sensors 420, 422, such as by identifying particular one or more vacuum nozzles 110, 410 related to a particular bond radius measurement, for control of release timing during the direct bonding process.

In some implementations, the corrective action can be independent of any eccentricity measured of a specific bond front that is detected in situ, such that the corrective action can involve determining an ideal or optimum vacuum release timing that can be repeated for similar W2W bonds. For example, the optimum vacuum release timing can be stored in a process data repository 1330 (see FIG. 13) and applied to subsequent W2W bonds.

FIG. 5B shows an alternate embodiment with three (3) optical sensors 422-1, 422-2, and 422-3 in wafer platen 501 that can be used for providing an indication of eccentricity of the direct bond front in situ. Although optical sensors 422 are shown in outer vacuum zone 502-1, optical sensors 422 can be collectively located at a different radius with respect to the center of wafer platen 501.

Thus, optical sensors 420, 422 can be used to detect the bond front by measuring a vertical distance to second wafer 104 as the bond progresses. Optical sensors 420, 422 may output a time signal indicating when the bond front arrives or is registered by the vertical distance measurement. In various implementations, optical sensors 420, 422 can be used in conjunction with horizontal optical sensor 120 to obtain bond front propagation measurements in situ and to use the bond front propagation measurements to perform a corrective action during the direct bond, as disclosed herein. For example, a distance to the bond front measured using horizontal optical sensor 120 can be correlated in time to a vertical displacement measured by optical sensors 420, in various implementations.

FIG. 6 is a depiction of multiple radial measurements 600 (or simply measurements 600) of a W2W bond, in some implementations. FIG. 6 depicts an arrangement of three (3) horizontal optical sensors 120-1, 120-2, and 120-3 that are mounted at different fixed radial locations of gap 122 that are shown with respect to a top view 602 of gap 122. FIG. 6 and measurements 600 are shown schematically for descriptive purposes and correspond to W2W bonding shown and described above in the previous figures. For example, horizontal optical sensor 120-1 emitting laser beam 108-1 can be mounted at an angular location corresponding to 90 degrees (e.g, a Y-axis), horizontal optical sensor 120-2 emitting laser beam 108-2 can be mounted at an angular location corresponding to 0 degrees (e.g., an X-axis), while horizontal optical sensor 120-3 emitting laser beam 108-3 can be mounted at an angular location corresponding to 135 degrees, where laser beams 108 at the angular locations are in the plane of gap 122.

Accordingly, horizontal optical sensors 120 in FIG. 6 can be used to measure bond radii R1, R2, R3 at the respective angular locations, as shown, such as substantially simultaneously in situ during the W2W bond front propagation, as described herein. Specifically, given a known radius of gap 122 (corresponding to a radius of first wafer 102 and second wafer 104 that is assumed to be equivalent), as well as given a known position of horizontal optical sensors 120 relative to an edge of gap 122 (or to an edge of first wafer 102 or second wafer 104 that are assumed to be precisely aligned), from the distance measurements D1, D2, D3 shown in Wafer bonding process 300, corresponding values along R1, R2, R3 of bond radii at each angular location can be measured in situ, as the W2W bond front propagates outward (see FIGS. 7 and 8). Although three (3) horizontal optical sensors 120 are shown in FIG. 6, fewer or more horizontal optical sensors 120 can be used in different implementations.

FIG. 7 is a depiction of propagation of a bond front of a W2W bond 704, in some implementations. Specifically, FIG. 7 depicts a top view 602 of gap 122 with radii R1, R2, and R3 at the same angular locations as in FIG. 6. Overlaid on top view 602 are contours of the W2W bond fronts 704-1, 704-2, and 704-3 representing outward propagation of W2W bond 704 over a period of time, such as three (3) seconds in particular implementations. It is noted that the period of time is a general value used for descriptive purposes with respect to FIGS. 7 and 8 and that actual W2W bond front propagation times may vary in different implementations.

Thus, as shown as an example in FIG. 7, at 1 second after the W2W bond is initiated at the central portion of top view 602, the first contour 704-1 shows the bond front as a line as well as a bond area at the instant enclosed by the line. The second contour 704-2 is similarly shown at 2 seconds after initiating the bond front, while the third contour 704-3 is similarly shown at 3 seconds after initiating the bond front. Because a front, or edge, of W2W bond 704 can propagate outward in a relatively concentric and radially balanced manner, W2W bond 704 can be an example of a W2W bond having nominal variance to an acceptable tolerance, such that the front of W2W bond 704 propagates more or less uniformly from the wafer center to the wafer edge in a circumferential manner, and does not result in any misalignment of the wafers, with a uniform bond integrity across gap 122.

However, it is apparent from FIG. 7 that, in cases where the bond front does not propagate uniformly, or has greater than nominal variance to the acceptable tolerance, measurements of the bond radius R1, R2, R3 can provide information indicative of the excessive variance of the propagation of the bond front, for example. As shown and explained above with respect to FIG. 6, such bond radii measurements R1, R2, R3 can be performed in situ during the W2W bonding process and can be used to indicate a correction or modification of the direct bonding in progress (in situ) using a corrective action, such as to remediate or correct for the excessive variance or excessive eccentricity across the wafers, and result in a W2W bond that is still within the acceptable tolerance, which is desirable. Depending on the specific application, a detected variation may involve some type of correction. In some embodiments, a corrective action may be taken either during the bonding process or in a subsequent bonding process when the variation in bond radii at predetermined times is above a certain threshold, such as greater than 5%.

FIG. 8 is a plot 800 of in situ bonding radii measurements during a W2W bonding process, in some implementations. Specifically, plot 800 shows bonding radii measurements of W2W bond 704 versus time, as described above with respect to FIG. 7. From plot 800, a relatively tight correlation of radii R1, R2, R3 over time can indicate that W2W bond 704 is propagating within the acceptable tolerance. For example, plot 800 (or a similar mathematical or abstract depiction) can be used to define and graphically portray the limits of the acceptable tolerance, such as in order to recognize in situ when a nominal variance to the acceptable tolerance is exceeded. For example, if one curve R1, R2, R3 in plot 800 deviates significantly from the other curves, such deviation can be indicative that the nominal variance of eccentricity of the bond front was exceeded, and some in situ remedial action of the direct bonding process is indicated to preserve the integrity of the W2W bond. It is noted that additional bond radii can be measured in situ resulting in additional curves in plot 800 that can be used to increase an accuracy of detecting the variance to the acceptable tolerance or to minimize the variance using corrective actions as described herein.

For example, depending on which curve R1, R2, R3, as well as a value of the respective curve, exceeds the nominal variance, a particular one or more of vacuum nozzles 110 (see FIG. 2), such as at radial locations vacuum pressure can be adjusted, can be identified. In this manner, during a W2W direct bonding process, the various parameters associated with the bond front propagation can be modified for individual wafer pairs to be bonded. The nominal variance can define a maximum degree of eccentricity of the bond front during propagation of the bond front, with respect to a center of second wafer 104 that is aligned with a center of first wafer 102. Depending on the bonding process, a variation in slope of 5% or more may be considered to require corrective action, however, any variation between 1 and 10% may be corrected.

Although FIGS. 6, 7, and 8 are shown and described using three (3) horizontal optical sensors 120 corresponding to 3 radii measurements R1, R2, R3, in other implementations, a larger number of horizontal optical sensors 120 can be used for more radii measurements, to more completely or more accurately or with greater sensitivity, determine any excessive variance from the acceptable tolerance (e.g., eccentricity of the bond front with respect to the center). In this manner, a misalignment during the W2W bonding process can be detected in situ and may also be remediated in situ, as described herein. Furthermore, the bond radii measurements, among other information associated with a given W2W bonding operation or process, can be recorded and used as wafer-level validation of any 3D IC parts fabricated, which can be desirable for ongoing quality control purposes. The information associated with a given W2W bonding operation or process can be stored in a process data repository 1330 (see FIG. 13).

As noted previously, backscattered light can be received by an optical detector included with horizontal optical sensor 120 (see FIG. 10) that can be used to generate the distance measurements for measuring W2W bond radii, such as R1, R2, R3. Furthermore, as noted, horizontal optical sensor 120 can operate using various methods to calibrate a distance measurement from horizontal optical sensor 120 from the backscattered light, such as by time multiplexing, frequency modulation, code modulation, phase modulation, amplitude modulation, among other signal processing techniques. For example, a ToF measurement method can be used to measure a time interval between emission of laser beam 108 and reception of backscattered photons from gap 122 during W2W bonding, in some implementations. The ToF can be given by d=(c*t)/2, where d is the distance corresponding to time interval t. In some implementations, laser beam 108 may comprise optical pulses for ToF distance measurements or other types of distance measurements.

As noted different types of measurements using the backscattered light can be used in different implementations. In some implementations, diffuse reflection from laser beam 108 can be used for measuring distance to the W2W bond front, such as by illuminating gap 122 using laser beam 108. In some cases, the optical detector can comprise a 2-dimensional (2D) array of pixel sensor and can be used to generate 2D image data from the pixel sensors receiving the backscattered light. For example, the backscattered light from the bond front during W2W bonding may comprise a relatively weak signal as compared to an intensity of laser beam 108. The backscattered light may be elastically or inelastically backscattered from various portions of gap 122, such as slightly concave upward curved portions of second wafer 104 (see FIGS. 3A-3D), such that the backscattered light includes non-linear distance information or provides some ambiguity, even when calibrated with known values for the bond front.

In such cases, various methods can be used to calibrate the backscattered light to the distance value for performing the distance measurement using horizontal optical sensor 120. In particular implementations, a machine learning (ML) model can be used in the form of a neural network to provide a calibration function between backscattered 2D images and distance to the bond front from horizontal optical sensor 120, as described with respect to FIG. 9.

FIG. 9 is a depiction of an ML model 900 for W2W bond distance calibration, in some implementations. ML model 900 is depicted as a neural network architecture having an input layer 910, internal layers 912, 914, and an output layer 916. ML model 900 is a general representation that can be applied to receive input data 906 (e.g., backscattered 2D image data) and generate distance measurements 930. Accordingly, input data 906 can be supplied to ML model 900 as input layer 910, while distance measurements 930 can be received from ML model 900 from output layer 916 in various implementations. It is noted that although ML model 900 is depicted with a small set of nodes or artificial neurons (referred to herein as simply “neurons”), the dimensionality and structure of ML model 900 can be adapted for various specific types of data. For example, as shown, ML model 900 can be expanded to a number of input neurons, y number of input layers each having b . . . x number of neurons, and z number of output neurons. It is noted that a, b . . . x, y, and z can each have different dimensions, such as 103, 106, 109, 1012, among other values in various embodiments.

In the mathematical processing of ML model 900 of FIG. 9, the processing at each layer can be represented by an activation expression that can be generalized by Expression 1.

$${\sum }_{i} ( {w}_{i} {x}_{i} ) + b \qquad Expression 1$$

In Expression 1, i represents an index variable or dimension for each layer input, such as a, b . . . x, and z in FIG. 9; x represents the input value at each neuron, such as from another neuron; w represents a weighting coefficient applied at each neuron; and b represents a constant for each neuron. The output of each neuron can be represented by an activation function having the result of Expression 1 (e.g., the activation expression) as a parameter. In particular, ML model 900 may employ deep learning (DL) as a form of artificial intelligence (AI) that can be used to determine higher level complex data abstractions with a hierarchical, layered neural network architecture to enable learning. ML model 900 may learn by stating, describing, and implementing higher level, more abstract features on top of lower level, less abstract features. In this manner, ML model 900 can employ DL to analyze and learn from a large amount of unstructured data that can be unlabeled as well as uncategorized. For example, weighting coefficients and constants from Expression 1 can be seeded with random values in an implementation of ML model 900 for calibration of distance measurements from 2D backscattered image data than can be used to calculate W2W bond radii.

For W2W bond distance calibration, the backscattered 2D images of calibrated distances to the bond front, such as by using a secondary IR measurement method or the optical sensors such as 420 to obtain the calibrated distance value, can be used to train ML model 900. For example, a certain number of individual W2W bonds can be used for training ML model to achieve a given performance or accuracy of the distance calibration. Once ML model 900 has been trained for distance calibration in this manner, ML model 900, such as comprising the layer parameters associated with Expression 1 above, can be exported and used with horizontal optical sensor 120 as a calibration function. ML model 900 may perform with a desired accuracy in this manner even when the functionality or meaning of layer parameters of internal layers 912, 914 (or additional layers) remains undefined or unknown. For example, a backpropagation technique can be used for training that minimizes a cost function associated with incorrect calibration output of ML model 900, to iteratively ascertain suitable values for the layer parameters that perform the W2W bond distance calibration to an acceptable degree.

FIG. 10 is a depiction of an optical sensor in some implementations. Although described using horizontal optical sensor 120, FIG. 10 may be representative of vertical optical sensors 420, 422 described above in some embodiments. In FIG. 10, a horizontal optical sensor 120 is shown emitting laser beam 108, as described previously, from a laser source 1002. Laser source 1002 can be selected from a variety of wavelengths, such as wavelengths shorter than about 1,100 nm when the wafers for W2W bonding comprise silicon. Horizontal optical sensor 120 also includes optical detector 1004 that receives backscattered light 1006 and that can be selected for sensitivity to wavelengths at or near the wavelength(s) emitted by laser source 1002. In particular implementations, optical detector 1004 includes a 2D array of pixel sensors and can accordingly generate output signals that include 2D image data from the pixel sensors. The pixel sensors can be various types of photosensitive devices, such as photodiodes, phototransistors, photoconductors, photovoltaic elements, photoelectric elements, metal-silicon-metal (MSM) semiconductor elements, among others.

As shown in FIG. 10, horizontal optical sensor 120 also includes a processor 1010 having access to a memory 1012 storing instructions 1014 that are executable by processor 1010. At least certain portions of the methods and operations described herein for in situ W2W bond radii measurements, among other disclosed methods and operations, can be implemented in instructions 1014 and executed by processor 1010. Processor 1010 can also control operation of laser source 1002 and optical detector 1004, as well as an I/O interface 1016 that can comprise various types of communication interfaces for communication of data and commands to and from horizontal optical sensor 120. In some implementations, I/O interface 1016 can include wireless interfaces. I/O interface 1016 can accordingly support analog signals or digital signals for communication with external devices and systems. Horizontal optical sensor 120 can further include a power source, such as an internal battery or can receive power from an external source.

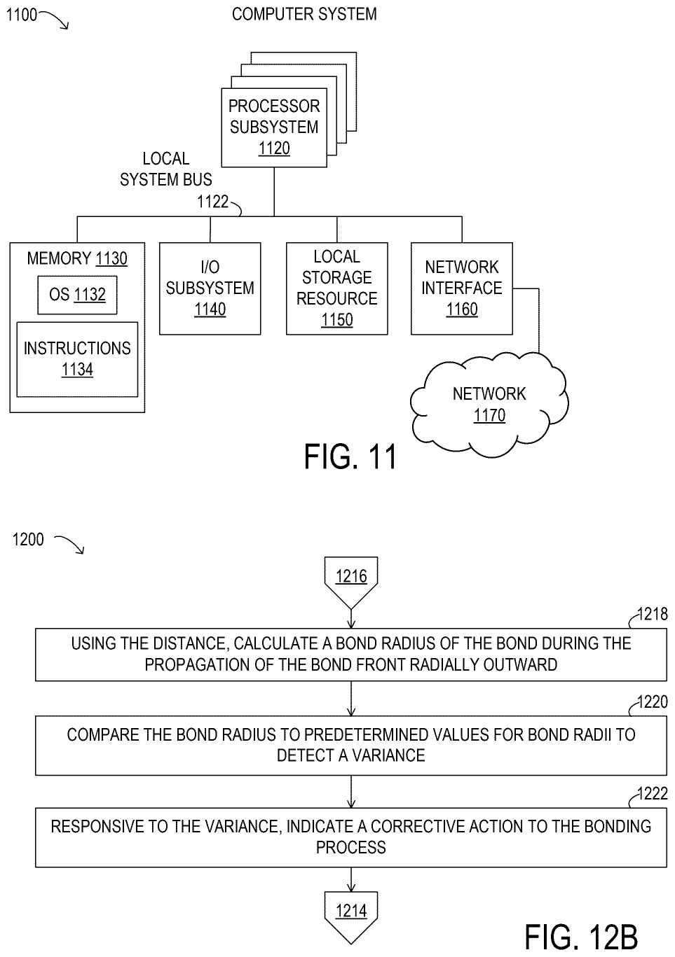

FIG. 11 is a depiction of a computer system 1100, in some implementations. Implementations described herein may be implemented using computer system 1100. Accordingly, computer system 1100 may represent any of a variety of computer systems or computing devices, such as personal computers, desktop computers, laptops, servers, blade computers, modular computers, and compute nodes, among others.

As shown in FIG. 11, computer system 1100 includes a processor subsystem 1120, a memory 1130, a local storage resource 1150, a network interface 1160, an input/output (I/O) subsystem 1140, and a local system bus 1122 for interconnecting various local elements with processor subsystem 1120. Network interface 1160 may enable connection to a network 1170, described in further detail below. In particular implementations, processor subsystem 1120 may interpret and execute program instructions and process data stored remotely (e.g., in a network storage resource accessible using network interface 1160).

In FIG. 11, system bus 1122 may represent a variety of suitable types of bus structures, e.g., a memory bus, a peripheral bus, or a local bus using various bus architectures in selected implementations.

Also in FIG. 11, memory 1130 may include a system, device, or apparatus operable to retain and retrieve program instructions and data for a period of time (e.g., computer-readable media). Memory 1130 may include volatile memory such as random access memory (RAM), a cache memory, magnetic memory, among others. In FIG. 11, memory 1130 is shown including an operating system (OS) 1132, which may represent an execution environment for various program code executing on computer system 1100. OS 1132 may be any of a variety of standard or customized operating systems, such as but not limited to a Microsoft Windows® operating systems, a UNIX or a UNIX-based operating system. Memory 1130 is also shown including instructions 1134 that represent at least some portions the methods and systems described herein for in situ W2W bond radii measurements, such as instructions executable by processor subsystem 1120.

In computer system 1100, I/O subsystem 1140 may include a system, device, or apparatus generally operable to receive and transmit data to or from or internally within computer system 1100. In particular implementations, I/O subsystem 1140 is compatible with I/O interface 1326 to support communication with one or more horizontal optical sensors 120 (see FIG. 13).

In FIG. 11, local storage resource 1150 may comprise non-volatile or persistent computer-readable media such as a hard disk drive, CD-ROM, and other type of rotating storage media, flash memory, EEPROM, or another type of solid state storage media, and may be generally operable to store instructions and data, and to permit access to stored instructions and data on demand.

Further, in FIG. 11, network interface 1160 may facilitate connecting computer system 1100 to network 1170, which may represent a local area network (LAN), a wide area network (WAN) such as the Internet, mobile network, or another type of network. Network interface 1160 can provide communication with another device, such as another computer system or one or more horizontal optical sensors 120.

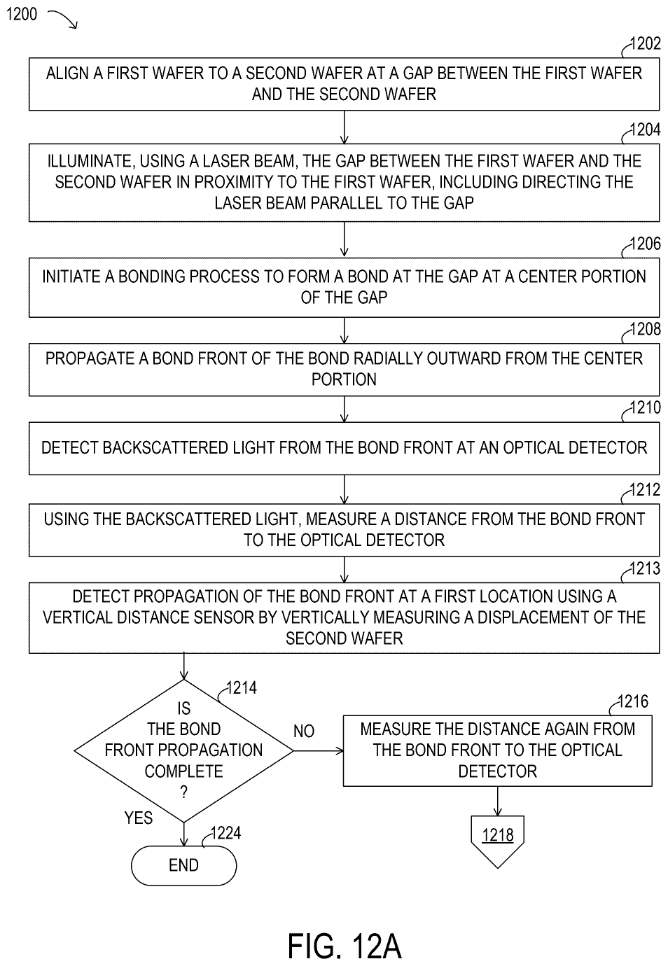

FIGS. 12A and 12B are a flowchart depicting a method 1200 for wafer bonding, in some implementations. It is noted that certain operations in method 1200 may be rearranged or omitted in various embodiments. Method 1200 can be performed using wafer bonding apparatus 100 or 400, in particular implementations.

Method 1200 may begin at step 1202 by aligning a first wafer to a second wafer at a gap between the first wafer and the second wafer. At step 1204, using a laser beam, the gap between the first wafer and the second wafer in proximity to the first wafer is illuminated, including directing the laser beam parallel to the gap. At step 1206, a bonding process to form a bond at the gap is initiated at a center portion of the gap. The bonding process can be a direct bond process and the bond can be a direct bond. At step 1208, a bond front of the bond is propagated radially outward from the center portion. At step 1210, backscattered light from the bond front is detected at an optical detector. At step 1212, using the backscattered light, a distance from the bond front to the optical detector is measured. At step 1213, propagation of the bond front is detected at a first location using an optical sensor by vertically measuring a displacement of the second wafer. At step 1214, a decision is made whether the bond front propagation is complete. When the result of step 1214 is NO, at step 1216, the distance is again measured from the bond front to the optical detector. After step 1216, method 1200 continues to step 1218 (FIG. 12B) by, using the distance, calculating a bond radius of the bond during the propagation of the bond front radially outward. At step 1220, the bond radius is compared to predetermined values for bond radii to detect a variance. At step 1222, responsive to the variance, a corrective action is indicated to the bonding process. After step 1222, method 1200 loops back to step 1214. When the result of step 1214 is YES, method 1200 ends at step 1224.

FIG. 13 is a depiction of a wafer bonding control system 1300, in some implementations. Wafer bonding control system 1300 (or simply, control system 1300) can be used for various measurements and corrective actions or other tasks associated with wafer bonding, as disclosed herein. As shown, control system 1300 includes a controller 1320 having a memory 1322 storing instructions 1324 executable by controller 1320. In some embodiments, controller 1320 can be an implementation of computer system 1100 described above. Accordingly, memory 1322 can be similar to memory 1130 described above, while instructions 1324 can be similar to instructions 1134 (see FIG. 11). Control system 1300 also includes (or is interfaced to) a wafer bonding apparatus 1310 that may represent wafer bonding apparatus 100 or 400 in various implementations.

In control system 1300, controller 1320 also includes an I/O interface 1326 that can be used for communication, such as over a network, to communicate with a measurement interface 1312, a control interface 1314, and a process data repository 1330. I/O interface 1326 can include a network interface. Process data repository 1330 can be a database associated with a wafer bonding process, as disclosed herein, and can be used to record and maintain various process data, such as for operating wafer bonding apparatus 100 or 400. Accordingly, process data repository 1330 can store various data, such as process parameters or ‘recipes’ for performing direct bonding of first wafer 102 with second wafer 104, including various process timings defining a release sequence of vacuum nozzles 110, 410, and/or otherwise controlling a vacuum pressure of vacuum nozzles 110, 410.

Accordingly, control interface 1314 may be in communication with controller 1320 and can send/receive control signals 1318 to control various process parameters associated with wafer bonding apparatus 1310. Measurement interface 1312 can send/receive measurement signals 1316 that can include various bond front propagation measurements, as disclosed herein, from wafer bonding apparatus 1310. In response to receiving the bond front propagation measurements, instructions 1324 can include instructions to send commands to control interface 1314, such as to perform a corrective action during the bonding process. The corrective action can include, among other actions, at least one of: modifying a vacuum pressure associated with the at least one vacuum nozzle, modifying a release time associated with the at least one vacuum nozzle, modifying a selection of the at least one vacuum nozzle for applying the vacuum pressure, or modifying a release sequence of the at least one vacuum nozzle.

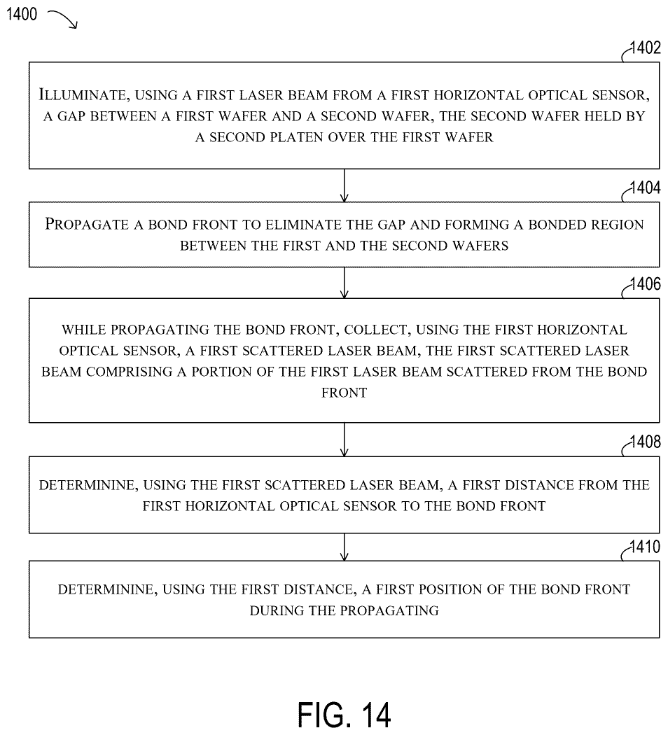

FIG. 14 is a flowchart depicting a depicting a method 1400 for measuring bond front propagation during direct bonding. It is noted that certain operations in method 1400 may be rearranged or omitted in various embodiments. Method 1400 can be performed using wafer bonding apparatus 100 or 400, in particular implementations.

Method 1400 begins at step 1402. At step 1402, using a first laser beam from a first horizontal optical sensor, a gap between a first wafer and a second wafer is illuminated, the second wafer being held by a second platen over the first wafer. At step 1404, a bond front is propagated to eliminate the gap and form a bonded region between the first and the second wafers. At step 1406, while propagating the bond front, using a horizontal optical detector a scattered laser beam is collected, the scattered laser beam comprising a portion of the laser beam scattered from the propagating bond front. At step 1408, using the scattered laser beam, a distance from the first horizontal optical sensor to the bond front is determined. At step 1410, using the distance, a position of the bond front is determined during the propagating.

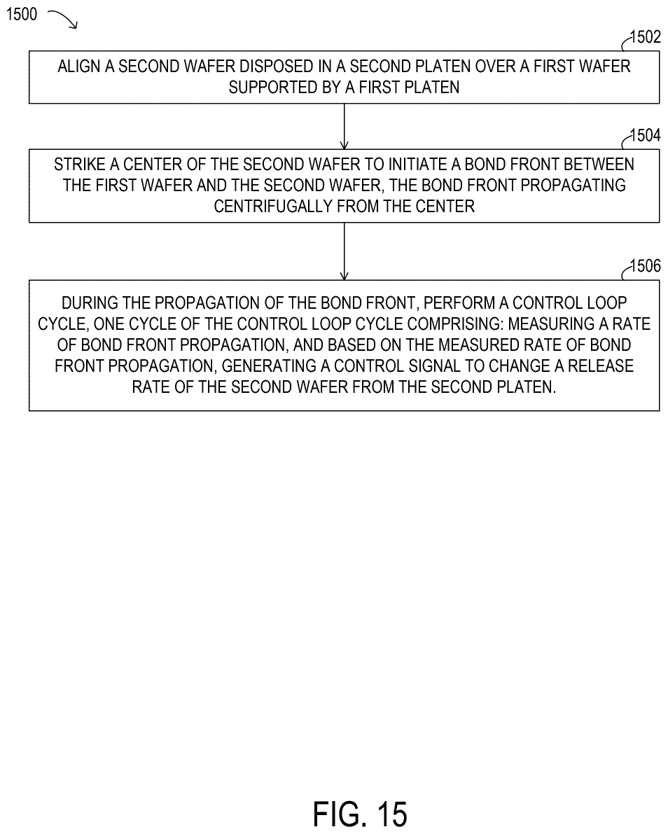

FIG. 15 is a flowchart depicting a depicting a method 1500 for controlling a direct bonding process. It is noted that certain operations in method 1500 may be rearranged or omitted in various embodiments. Method 1500 can be performed using wafer bonding apparatus 100 or 400, in particular implementations.

Method 1500 can begin at step 1502. At step 1502, a second wafer disposed in a second platen is aligned over a first wafer supported by a first platen. At step 1504, a center of the second wafer is struck to initiate a bond front between the first wafer and the second wafer, the bond front propagating centrifugally from the center. At step 1506, during the propagation of the bond front, a control loop cycle is performed, one cycle of the control loop cycle comprising: measuring a rate of bond front propagation, and based on the measured rate of bond front propagation, generating a control signal to change a release rate of the second wafer from the second platen. At step 1506, the second platen can include a plurality of vacuum nozzles, while the control signal can include information to change a vacuum pressure associated with one of the vacuum nozzles, a release time associated with one of the vacuum nozzles, a selection of one of the vacuum nozzles for applying the vacuum pressure, or a release sequence of one of the vacuum nozzles.

Example embodiments are described below. Other embodiments can also be understood from the entirety of the specification as well as the claims filed herein.

Example 1. A method for measuring bond front propagation during bonding includes illuminating, using a first laser beam from a first horizontal optical sensor, a gap between a first wafer and a second wafer, the second wafer held by a second platen over the first wafer. The method includes propagating a bond front to eliminate the gap and forming a bonded region between the first and the second wafers. The method includes while propagating the bond front, collecting, using the first horizontal optical sensor, a first scattered laser beam, the first scattered laser beam including a portion of the first laser beam scattered from the bond front. The method includes determining, using the first scattered laser beam, a first distance from the first horizontal optical sensor to the bond front; and determining, using the first distance, a first position of the bond front during the propagating.

Example 2. The method of example 1, further including: illuminating, using a second laser beam from a second horizontal optical sensor, the gap between the first wafer and the second wafer; while propagating the bond front, collecting, using the second horizontal optical sensor, a second scattered laser beam, the second scattered laser beam including a portion of the second laser beam after being scattered from the bond front; and determining, using the second scattered laser beam, a second distance from the second horizontal optical sensor to the bond front; and based on the first distance and the second distance, determining a contour of the bond front during the propagating.

Example 3. The method of one of examples 1 or 2, where the contour of the bond front includes an eccentricity of a shape of the bond front.

Example 4. The method of one of examples 1 to 3, where determining the contour includes comparing an image including the first distance and the second distance with an image of stored bond process data using a machine learning model.

Example 5. The method of one of examples 1 to 4, where the second platen includes a plurality of vacuum nozzles, where the second wafer is held by the second platen using the plurality of vacuum nozzles.

Example 6. The method of one of examples 1 to 5, further including: based on the first position of the bond front, changing a parameter of the plurality of vacuum nozzles.

Example 7. The method of one of examples 1 to 6, where changing the parameter includes: modifying a vacuum pressure associated with one of the vacuum nozzles; modifying a release time associated with one of the vacuum nozzles; modifying a selection of one of the vacuum nozzles for applying the vacuum pressure; or modifying a release sequence of one of the vacuum nozzles.

Example 8. The method of one of examples 1 to 7, further including: based on the first position of the bond front, changing a release rate of the second wafer from the second platen.

Example 9. The method of one of examples 1 to 8, where propagating the bond front is initiated by pushing a bonding pin through the second platen and pressing the second wafer into contact with the first wafer.

Example 10. The method of one of examples 1 to 9, further including: based on the first position of the bond front, generating a feedforward control signal for indicating a corrective action to be performed for a subsequent direct bonding process.

Example 11. The method of one of examples 1 to 10, further including: determining a contour of the bond front based on the first position of the bond front; and while propagating the bond front, further collecting, using a vertical optical sensor disposed in the second platen, a vertical displacement between the second wafer and the second platen, where determining the contour further includes using the vertical displacement.

Example 12. The method of one of examples 1 to 11, further including: determining a contour of the bond front based on the first position of the bond front; and while propagating the bond front, further collecting, using vertical optical sensors disposed in the second platen, vertical displacements between the second wafer and the second platen, where determining the first position further includes using the vertical displacements, and where the vertical optical sensors are arranged at different radial angle at a same radial location in the second platen.

Example 13. The method of one of examples 1 to 12, further including: while propagating the bond front, further collecting, using vertical optical sensors disposed in the second platen, vertical displacements between the second wafer and the second platen, where determining the contour further includes using the vertical displacements, and where the vertical optical sensors are arranged at multiple radial locations at multiple radial angles in the second platen.

Example 14. An apparatus for measuring bond front propagation during direct bonding includes a first platen for supporting a first wafer; a second platen for holding a second wafer; and one or more first optical sensors disposed around the first and the second platens, where each of the one or more first optical sensors is configured to measure propagation data including a horizontal distance to a bond front propagating between the first and the second wafers held between the first and the second platens.

Example 15. The apparatus of example 14, further including: a bonding pin configured to move through a central through hole disposed in the second platen.

Example 16. The apparatus of one of examples 14 or 15, where the one or more first optical sensors include Time-of-Flight (ToF) sensors.

Example 17. The apparatus of one of examples 14 to 16, further including: one or more second optical sensors disposed in the second platen, the second optical sensors being configured to collect one or more vertical displacements between the second wafer and the second platen while the bond front propagates.

Example 18. The apparatus of one of examples 14 to 17, where the second optical sensors include Time-of-Flight (ToF) sensors.

Example 19. The apparatus of one of examples 14 to 18, where the second optical sensors are arranged at different radial angle at a same radial location.

Example 20. The apparatus of one of examples 14 to 19, where the second optical sensors are arranged at multiple radial locations at multiple radial angles.

Example 21. The apparatus of one of examples 14 to 20, further including one or more processors coupled to a memory storing a program to be executed in the one or more processors, the program including instructions to calculate, from the propagation data, a contour of the bond front for a position of the bond front.

Example 22. The apparatus of one of examples 14 to 21, where the second platen includes a vacuum chuck including a plurality of vacuum zones, the program including instructions to determine a release time for each of the plurality of vacuum zones based on the propagation data.

Example 23. A method for controlling a direct bonding process includes aligning a second wafer disposed in a second platen over a first wafer supported by a first platen; striking the second wafer to initiate propagation of a bond front between the first wafer and the second wafer; and during the propagation of the bond front, performing a control loop cycle, one cycle of the control loop cycle including: measuring a rate of bond front propagation; and based on the measured rate of bond front propagation, generating a control signal to change a release rate of the second wafer from the second platen.

Example 24. The method of example 23, where measuring the rate of bond front propagation includes: optically measuring a horizontal distance of the bond front to a first optical sensor aligned to emit a light beam parallel to a plane between the first wafer and the second wafer, the control signal being generated based on the horizontal distance.

Example 25. The method of one of examples 23 or 24, where the one cycle of the control loop cycle further includes optically measuring, using a second optical sensor, a vertical distance between the second wafer and the second platen, where the control signal is determined based on both the horizontal distance and the vertical distance.

Example 26. The method of one of examples 23 to 25, where the first and the second optical sensors include a Time-of-Flight (ToF) sensor.

Example 27. The method of one of examples 23 to 26, where the second platen includes a plurality of vacuum nozzles, and where the control signal includes information to change a vacuum pressure associated with one of the vacuum nozzles, a release time associated with one of the vacuum nozzles, a selection of one of the vacuum nozzles for applying the vacuum pressure, or a release sequence of one of the vacuum nozzles.

Example 28. A method for measuring bond front propagation during direct bonding, the method including: illuminating, using a plurality of laser beams from a plurality of light sources, a gap between a first wafer and a second wafer, the second wafer held by a second platen over the first wafer, the plurality of laser beams aligned along a centripetal direction of the first wafer; propagating a bond front in a centrifugal direction from a center of the first and the second wafers to eliminate the gap and form a bonded region between the first and the second wafers; while propagating the bond front, collecting, using a plurality of optical detectors disposed around the first and the second wafers, a plurality of reflected laser beams, each of the plurality of reflected laser beams including a reflected portion of one of the plurality of laser beams reflected from the propagating bond front; determining, using the plurality of reflected laser beams, a plurality of distances, each of the plurality of distances including a distance from each of the plurality of light sources to the propagating bond front; and determining, using the plurality of distances, a contour of the bond front for a position of the bond front propagating in the centrifugal direction.

Example 29. The method of example 28, further including: based on the contour of the bond front, changing a release rate of the second wafer from the second platen.

Example 30. The method of one of examples 28 or 29, further including: while propagating the bond front, further collecting, using a plurality of optical sensors disposed in the second platen, a plurality of vertical displacements between the second wafer and the second platen, where determining the contour further includes using the plurality of vertical displacements.

Example 31. The method of one of examples 28 to 30, where the plurality of optical sensors is arranged at different radial angle at a same radial location in the second platen.

Example 32. The method of one of examples 28 to 31, where the plurality of optical sensors is arranged at multiple radial locations at multiple radial angles in the second platen.

Example 33. An apparatus for measuring bond front propagation during direct bonding, the apparatus including: a first platen for supporting a first wafer; a second platen for holding a second wafer and including a central through hole; a bonding pin configured to move through the central through hole of the second platen; a plurality of laser sensors disposed around the first and the second platens, each of the laser sensors being configured to measure propagation data including a distance to a bond front propagating between the first and the second wafers held between the first and the second platens; and one or more processors coupled to a memory storing a program to be executed in the one or more processors, the program including instructions to calculate, from the propagation data, a contour of the bond front for a position of the bond front.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

While this disclosure has been described with reference to illustrative embodiments, this description is not intended to be construed in a limiting sense. Various modifications and combinations of the illustrative embodiments, as well as other embodiments, will be apparent to persons skilled in the art upon reference to the description. It is therefore intended that the appended claims encompass any such modifications or embodiments.

1. A method for measuring bond front propagation during bonding, the method comprising:
illuminating, using a first laser beam from a first horizontal optical sensor, a gap between a first wafer and a second wafer, the second wafer held by a second platen over the first wafer;
propagating a bond front to eliminate the gap and forming a bonded region between the first and the second wafers;
while propagating the bond front, collecting, using the first horizontal optical sensor, a first scattered laser beam, the first scattered laser beam comprising a portion of the first laser beam scattered from the bond front;
determining, using the first scattered laser beam, a first distance from the first horizontal optical sensor to the bond front; and
determining, using the first distance, a first position of the bond front during the propagating.

2. The method of claim 1, further comprising:
illuminating, using a second laser beam from a second horizontal optical sensor, the gap between the first wafer and the second wafer;
while propagating the bond front, collecting, using the second horizontal optical sensor, a second scattered laser beam, the second scattered laser beam comprising a portion of the second laser beam after being scattered from the bond front; and
determining, using the second scattered laser beam, a second distance from the second horizontal optical sensor to the bond front; and
based on the first distance and the second distance, determining a contour of the bond front during the propagating.

3. The method of claim 2, wherein the contour of the bond front comprises an eccentricity of a shape of the bond front.

4. The method of claim 2, wherein determining the contour comprises comparing an image comprising the first distance and the second distance with an image of stored bond process data using a machine learning model.

5. The method of claim 1, wherein the second platen comprises a plurality of vacuum nozzles, wherein the second wafer is held by the second platen using the plurality of vacuum nozzles.

6. The method of claim 5, further comprising:
based on the first position of the bond front, changing a parameter of the plurality of vacuum nozzles.

7. The method of claim 6, wherein changing the parameter comprises:
modifying a vacuum pressure associated with one of the vacuum nozzles;
modifying a release time associated with one of the vacuum nozzles;
modifying a selection of one of the vacuum nozzles for applying the vacuum pressure; or
modifying a release sequence of one of the vacuum nozzles.

8. The method of claim 1, further comprising:
based on the first position of the bond front, changing a release rate of the second wafer from the second platen.

9. The method of claim 1, further comprising:
based on the first position of the bond front, generating a feedforward control signal for indicating a corrective action to be performed for a subsequent direct bonding process.

10. The method of claim 1, further comprising:
determining a contour of the bond front based on the first position of the bond front; and
while propagating the bond front, further collecting, using a vertical optical sensor disposed in the second platen, a vertical displacement between the second wafer and the second platen, wherein determining the contour further comprises using the vertical displacement.

11. An apparatus for measuring bond front propagation during direct bonding, the apparatus comprising:
a first platen for supporting a first wafer;
a second platen for holding a second wafer; and
one or more first optical sensors disposed around the first and the second platens, each of the one or more first optical sensors being configured to measure propagation data comprising a horizontal distance to a bond front propagating between the first and the second wafers held between the first and the second platens.

12. The apparatus of claim 11, further comprising:
a bonding pin configured to move through a central through hole disposed in the second platen.

13. The apparatus of claim 11, wherein the one or more first optical sensors comprise Time-of-Flight (ToF) sensors.

14. The apparatus of claim 11, further comprising:
one or more second optical sensors disposed in the second platen, the second optical sensors being configured to collect one or more vertical displacements between the second wafer and the second platen while the bond front propagates.

15. The apparatus of claim 14, wherein the second optical sensors comprise Time-of-Flight (ToF) sensors.

16. The apparatus of claim 14, wherein the second optical sensors are arranged at different radial angle at a same radial location.

17. The apparatus of claim 14, wherein the second optical sensors are arranged at multiple radial locations at multiple radial angles.

18. The apparatus of claim 11, further comprising one or more processors coupled to a memory storing a program to be executed in the one or more processors, the program comprising instructions to calculate, from the propagation data, a contour of the bond front for a position of the bond front.

19. The apparatus of claim 18, wherein the second platen comprises a vacuum chuck comprising a plurality of vacuum zones, the program comprising instructions to determine a release time for each of the plurality of vacuum zones based on the propagation data.

20. A method for controlling a direct bonding process, the method comprising:
aligning a second wafer disposed in a second platen over a first wafer supported by a first platen;
striking the second wafer to initiate propagation of a bond front between the first wafer and the second wafer; and
during the propagation of the bond front, performing a control loop cycle, one cycle of the control loop cycle comprising:
measuring a rate of bond front propagation; and
based on the measured rate of bond front propagation, generating a control signal to change a release rate of the second wafer from the second platen.

21. The method of claim 20, wherein measuring the rate of bond front propagation comprises:
optically measuring a horizontal distance of the bond front to a first optical sensor aligned to emit a light beam parallel to a plane between the first wafer and the second wafer, the control signal being generated based on the horizontal distance.

22. The method of claim 21, wherein the one cycle of the control loop cycle further comprises optically measuring, using a second optical sensor, a vertical distance between the second wafer and the second platen, wherein the control signal is determined based on both the horizontal distance and the vertical distance.

23. The method of claim 20, wherein the second platen comprises a plurality of vacuum nozzles, and wherein the control signal comprises information to change a vacuum pressure associated with one of the vacuum nozzles, a release time associated with one of the vacuum nozzles, a selection of one of the vacuum nozzles for applying the vacuum pressure, or a release sequence of one of the vacuum nozzles.
